(19) United States
(12) Patent Application Publication
(10) Pub. No.: US 2011/0278595 A1
(43) Pub. Date: Nov. 17, 2011

(54) METHOD FOR MANUFACTURING SILICON CARBIDE SUBSTRATE, METHOD FOR MANUFACTURING SEMICONDUCTOR DEVICE, SILICON CARBIDE SUBSTRATE, AND SEMICONDUCTOR DEVICE

(75) Inventors: Taro Nishiguchi, Itami-shi (JP); Makoto Sasaki, Itami-shi (JP); Shin Harada, Osaka-shi (JP); Kyoko Okita, Itami-shi (JP); Hiroki Inoue, Itami-shi (JP); Yasuo Namikawa, Itami-shi (JP)

(73) Assignee: SUMITOMO ELECTRIC INDUSTRIES, LTD., Osaka-shi (JP)

(21) Appl. No.: 13/104,275

(22) Filed: May 10, 2011

(30) Foreign Application Priority Data
May 14, 2010 (JP) 2010-111972

(51) Int. Cl. H01L 29/24; C30B 23/02; H01L 21/20; B32B 13/04

(52) U.S. Cl. 257/77; 428/446; 117/106; 117/1; 438/478; 257/E29.104; 257/E21.09

(57) ABSTRACT

A method for manufacturing a silicon carbide substrate includes the steps of: preparing a base substrate made of silicon carbide and a SiC substrate made of single-crystal silicon carbide; fabricating a stacked substrate by placing said SiC substrate on and in contact with a main surface of said base substrate; and connecting said base substrate and said SiC substrate to each other by heating said stacked substrate in a container to fall within a range of temperature equal to or greater than a sublimation temperature of silicon carbide constituting said base substrate. In the step of connecting said base substrate and said SiC substrate, a silicon carbide body made of silicon carbide and different from said base substrate and said SiC substrate is disposed in said container.

### BACKGROUND OF THE INVENTION

1. Field of the Invention

The present invention relates to a method for manufacturing a silicon carbide substrate, a method for manufacturing a semiconductor device, a silicon carbide substrate, and a semiconductor device, more particularly, a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

2. Description of the Background Art

In recent years, in order to achieve high reverse breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high reverse breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

Under such circumstances, various silicon carbide crystals used in manufacturing of semiconductor devices and methods for manufacturing silicon carbide substrates have been considered and various ideas have been proposed (for example, see Japanese Patent Laying-Open No. 2002-280531).

However, silicon carbide does not have a liquid phase at an atmospheric pressure. In addition, crystal growth temperature thereof is 2000° C. or greater, which is very high. This makes it difficult to control and stabilize growth conditions. Accordingly, it is difficult for a silicon carbide single-crystal to have a large bore diameter while maintaining its quality to be high. Hence, it is not easy to obtain a high-quality silicon carbide substrate having a large bore diameter. This difficulty in fabricating such a silicon carbide substrate having a large bore diameter results in not only increased manufacturing cost of the silicon carbide substrate but also fewer semiconductor devices produced for one batch using the silicon carbide substrate. Accordingly, manufacturing cost of the semiconductor devices is increased, disadvantageously. It is considered that the manufacturing cost of the semiconductor devices can be reduced by effectively utilizing a silicon carbide single-crystal, which is high in manufacturing cost, as a substrate.

### SUMMARY OF THE INVENTION

In view of this, an object of the present invention is to provide a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

A method for manufacturing a silicon carbide substrate in the present invention includes the steps of: preparing a base substrate made of silicon carbide and a SiC substrate made of single-crystal silicon carbide; fabricating a stacked substrate by placing the SiC substrate on and in contact with a main surface of the base substrate; and connecting the base substrate and the SiC substrate to each other by heating the stacked substrate in a container to fall within a range of temperature equal to or greater than a sublimation temperature of silicon carbide constituting the base substrate. In the step of connecting the base substrate and the SiC substrate, a silicon carbide body made of silicon carbide and different from the base substrate and the SiC substrate is disposed in the container.

As described above, it is difficult for a high-quality silicon carbide single-crystal to have a large bore diameter. Meanwhile, for efficient manufacturing in a process of manufacturing a semiconductor device using a silicon carbide substrate, a substrate provided with predetermined uniform shape and size is required. Hence, even when a high-quality silicon carbide single-crystal (for example, silicon carbide single-crystal having a small defect density) is obtained, a region that cannot be processed into such a predetermined shape and the like by cutting, etc., may not be effectively used.

In contrast, in the method for manufacturing the silicon carbide substrate in the present invention, the silicon carbide substrate is manufactured by placing the SiC substrate made of single-crystal silicon carbide on the base substrate to fabricate the stacked substrate; and heating the stacked substrate to the range of temperature equal to or higher than the sublimation temperature of silicon carbide constituting the base substrate, so as to connect the base substrate and the SiC substrate to each other. Thus, the silicon carbide substrate can be manufactured, for example, in the following manner. That is, the base substrate formed of low-quality silicon carbide crystal having a large defect density is processed to have the predetermined shape and size. On such a base substrate, a high-quality silicon carbide single-crystal not shaped into the predetermined shape is placed as the SiC substrate. Then, they are heated. The silicon carbide substrate obtained in this way has the predetermined uniform shape and size as a whole. This contributes to improved efficiency in manufacturing semiconductor devices. Further, on the high-quality SiC substrate of such a silicon carbide substrate, an epitaxial growth layer is formed to manufacture a semiconductor device, for example. Thus, the silicon carbide single-crystal can be used effectively. As such, according to the method for manufacturing the silicon carbide substrate in the present invention, there can be manufactured a silicon carbide substrate that allows for reduced cost of manufacturing semiconductor devices using the silicon carbide substrate.

Further, in the above-described method for manufacturing the silicon carbide substrate, in the step of connecting the base substrate and the SiC substrate, the connection may not be sufficiently developed between the base substrate and the SiC substrate. The present inventor has studied and found that this is due to the following reason. That is, the connection between the base substrate and the SiC substrate are accomplished by heating the stacked substrate to fall within the range of temperature equal to or higher than the sublimation temperature of silicon carbide constituting the base substrate. Here, the connection is developed as follows: silicon carbide constituting the stacked substrate is sublimated to be sublimation gas, which is then recrystallized. However, when vapor pressure of the sublimation gas in the container for making the connection therein is smaller than the saturated vapor pressure, silicon, which is higher in vapor pressure than carbon, is selectively (preferentially) desorbed from the silicon carbide. This results in carbonization (graphitization) in the vicinity of surfaces of the base substrate and the SiC substrate. Accordingly, the sublimation of silicon carbide is prevented, whereby the connection is less likely to be developed between the base substrate and the SiC substrate.

To address this, in the method for manufacturing the silicon carbide substrate in the present invention, in the step of connecting the base substrate and the SiC substrate, the silicon carbide body made of silicon carbide and different from the base substrate and the SiC substrate is disposed in the container for making the connection therein. Accordingly, silicon carbide constituting the silicon carbide body is sublimated to increase the vapor pressure of the sublimation gas. This restrains the surfaces of the base substrate and the SiC substrate from being carbonized due to the above-described selective desorption of silicon. Accordingly, the connection resulting from the sublimation and recrystallization of silicon carbide is developed well between the base substrate and the SiC substrate.

In the above-described method for manufacturing the silicon carbide substrate, in the step of connecting the base substrate and the SiC substrate, the silicon carbide body may be heated to a temperature higher than those of the base substrate and the SiC substrate. Accordingly, the vapor pressure of the sublimation gas is likely to be increased.

In the above-described method for manufacturing the silicon carbide substrate, in the step of connecting the base substrate and the SiC substrate, the base substrate may be heated to a temperature higher than that of the SiC substrate. Accordingly, silicon carbide constituting the base substrate is mainly sublimated and recrystallized to achieve the connection between the base substrate and the SiC substrate. As a result, the silicon carbide substrate can be manufactured while maintaining quality of the SiC substrate such as crystallinity.

In the above-described method for manufacturing the silicon carbide substrate, the silicon carbide body is formed of bulk silicon carbide. This reduces restrictions as to a placement location of the silicon carbide body.

In the above-described method for manufacturing the silicon carbide substrate, the silicon carbide body may be formed of granular silicon carbide. Accordingly, silicon carbide constituting the silicon carbide body is efficiently sublimated to increase the vapor pressure of the sublimation gas readily.

In the above-described method for manufacturing the silicon carbide substrate, graphite may be employed as a material to form the container. Graphite is not only stable under a high temperature but also is readily processed and is relatively low in its material cost. Hence, graphite is suitable for the material of the container used in the step of connecting the base substrate and the SiC substrate because the stacked substrate needs to be heated therein to fall within the range of temperature equal to or higher than the sublimation temperature of silicon carbide in the step of connecting.

The above-described method for manufacturing the silicon carbide substrate may further include the step of smoothing main surfaces of the base substrate and the SiC substrate before the step of fabricating the stacked substrate, the main surfaces of the base substrate and the SiC substrate being to be brought into contact with each other in the step of fabricating the stacked substrate. By smoothing the surfaces, which are to be the connection surface between the base substrate and the SiC substrate, the base substrate and the SiC substrate can be connected to each other more securely.

In the above-described method for manufacturing the silicon carbide substrate, the step of fabricating the stacked substrate may be performed without polishing main surfaces of the base substrate and the SiC substrate before the step of fabricating the stacked substrate, the main surfaces of the base substrate and the SiC substrate being to be brought into contact with each other in the step of fabricating the stacked substrate. Hence, the manufacturing cost of the silicon carbide substrate can be reduced. Here, as described above, the main surfaces of the base substrate and the SiC substrate, which are to be brought into contact with each other in the step of fabricating the stacked substrate, may not be polished. However, for removal of damaged layers in the vicinity of surfaces formed by slicing upon fabricating the substrate, it is preferable to perform the step of fabricating the stacked substrate after performing a step of removing the damaged layers by means of etching, for example.

In the above-described method for manufacturing the silicon carbide substrate, in the step of fabricating the stacked substrate, a plurality of the SiC substrates may be placed and arranged side by side when viewed in a planar view. Explaining from a different point of view, the SiC substrates may be placed and arranged on and along the main surface of the base substrate.

As described above, it is difficult for a high-quality silicon carbide single-crystal to have a large bore diameter. To address this, the plurality of SiC substrates each obtained from a high-quality silicon carbide single-crystal are placed and arranged side by side when viewed in a planar view, and then the base substrate and the SiC substrates are connected to one another, thereby obtaining a silicon carbide substrate that can be handled as a substrate having a high-quality SiC layer and a large bore diameter. By using such a silicon carbide substrate, the process of manufacturing a semiconductor device can be improved in efficiency. It should be noted that in order to improve the efficiency of the process of manufacturing a semiconductor device, it is preferable that adjacent ones of the plurality of SiC substrates are arranged in contact with one another. More specifically, for example, the plurality of SiC substrates are preferably arranged in contact with one another in the form of a matrix.

In the above-described method for manufacturing the silicon carbide substrate, in the step of fabricating the stacked substrate, the SiC substrate may have a main surface opposite to the base substrate and having an off angle of not less than 50° and not more than 65° relative to a {0001} plane.

By growing single-crystal silicon carbide of hexagonal system in the <0001> direction, a high-quality single-crystal can be fabricated efficiently. From such a silicon carbide single-crystal grown in the <0001> direction, a silicon carbide substrate having a main surface corresponding to the {0001} plane can be obtained efficiently. Meanwhile, by using a silicon carbide substrate having a main surface having an off angle of not less than 50° and not more than 65° relative to the plane orientation of {0001}, a semiconductor device with high performance may be manufactured.

Specifically, for example, it is general that a silicon carbide substrate used in fabricating a MOSFET (Metal Oxide Semiconductor Field Effect Transistor) has a main surface having an off angle of approximately 8° or smaller relative to the plane orientation of {0001}. An epitaxial growth layer is formed on this main surface and an oxide film, an electrode, and the like are formed on this epitaxial growth layer, thereby obtaining a MOSFET. In this MOSFET, a channel region is formed in a region including an interface between the epitaxial growth layer and the oxide film. However, in the MOSFET having such a structure, a multiplicity of interface states are formed around the interface between the epitaxial growth layer and the oxide film, i.e., the location in which the channel region is formed, due to the substrate's main surface having an off angle of approximately 8° or smaller relative to the {0001} plane. This hinders traveling of carriers, thus decreasing channel mobility.

To address this, in the step of fabricating the stacked substrate, the SiC substrate has a main surface opposite to the base substrate and having an off angle of not less than 50° and not more than 65° relative to a {0001} plane, whereby the silicon carbide substrate to be manufactured will have an off angle of not less than 50° and not more than 65° relative to the {0001} plane of the main surface. This reduces the formation of the interface states. Accordingly, a silicon carbide substrate can be manufactured which allows for fabrication of a MOSFET having reduced on-resistance.

In the above-described method for manufacturing the silicon carbide substrate, in the step of fabricating the stacked substrate, the main surface of the SiC substrate opposite to the base substrate may have an off orientation which forms an angle of 5° or smaller relative to a <1-100> direction.

The <1-100> direction is a representative off orientation in a silicon carbide substrate. Variation in the off orientation resulting from variation in a slicing process of the process of manufacturing the substrate is adapted to be not more than 5° or smaller, which allows an epitaxial growth layer to be formed readily on the silicon carbide substrate.

In the above-described method for manufacturing the silicon carbide substrate, in the step of fabricating the stacked substrate, the main surface of the SiC substrate opposite to the base substrate can have an off angle of not less than −3° and not more than 5° relative to a {03-38} plane in the <1-100> direction.

Accordingly, channel mobility can be further improved in the case where a MOSFET is fabricated using the silicon carbide substrate. Here, setting the off angle at not less than −3° and not more than +5° relative to the plane orientation of {03-38} is based on a fact that particularly high channel mobility was obtained in this set range as a result of inspecting a relation between the channel mobility and the off angle.

Further, the “off angle relative to the {03-38} plane in the <1-100> direction” refers to an angle formed by an orthogonal projection of a normal line of the above-described main surface to a flat plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction.

It should be noted that the main surface preferably has a plane orientation of substantially {03-38}, and the main surface more preferably has a plane orientation of {03-38}. Here, the expression “the main surface has a plane orientation of substantially {03-38}” is intended to encompass a case where the plane orientation of the main surface of the substrate is included in a range of off angle such that the plane orientation can be substantially regarded as {03-38} in consideration of processing accuracy of the substrate. In this case, the range of off angle is, for example, a range of off angle of ±2° relative to {03-38}. Accordingly, the above-described channel mobility can be further improved.

In the above-described method for manufacturing the silicon carbide substrate, in the step of fabricating the stacked substrate, the main surface of the SiC substrate opposite to the base substrate may have an off orientation which forms an angle of 5° or smaller relative to a <11-20> direction.

The <11-20> direction is a representative off orientation in a silicon carbide substrate, as with the <1-100> direction. Variation in the off orientation resulting from variation in the slicing process of the process of manufacturing the substrate is adapted to be ±5°, which allows an epitaxial growth layer to be formed readily on the silicon carbide substrate.

In the above-described method for manufacturing the silicon carbide substrate, in the step of connecting the base substrate and the SiC substrate, the stacked substrate may be heated in an atmosphere obtained by reducing pressure of atmospheric air. Accordingly, the manufacturing cost of the silicon carbide substrate can be reduced.

In the above-described method for manufacturing the silicon carbide substrate, in the step of connecting the base substrate and the SiC substrate, the stacked substrate may be heated under a pressure higher than 10⁻¹ Pa and lower than 10⁴ Pa. This can accomplish the above-described connection using a simple device, and provide an atmosphere for accomplishing the connection for a relatively short time. As a result, the manufacturing cost of the silicon carbide substrate can be reduced.

A method for manufacturing a semiconductor device in the present invention includes the steps of: preparing a silicon carbide substrate; forming an epitaxial growth layer on the silicon carbide substrate; and forming an electrode on the epitaxial growth layer. In the step of preparing the silicon carbide substrate, the silicon carbide substrate is manufactured using the above-described method for manufacturing the silicon carbide substrate in the present invention. According to the method for manufacturing the semiconductor device in the present invention, the semiconductor device is manufactured using the silicon carbide substrate manufactured using the above-described method for manufacturing the silicon carbide substrate in the present invention. Accordingly, the manufacturing cost of the semiconductor device can be reduced.

A silicon carbide substrate according to the present invention is manufactured using the above-described method for manufacturing the silicon carbide substrate in the present invention. Accordingly, the silicon carbide substrate in the present invention allows for reduced cost in manufacturing semiconductor devices using the silicon carbide substrate.

A semiconductor device according to the present invention is manufactured using the method for manufacturing the semiconductor device of the present invention. Accordingly, the semiconductor device of the present invention is a semiconductor device manufactured with reduced cost.

As apparent from the description above; according to the method for manufacturing the silicon carbide substrate, the method for manufacturing the semiconductor device, the silicon carbide substrate, and the semiconductor device in the present invention, there can be provided a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view for illustrating a method for manufacturing a silicon carbide substrate.

FIG. 2 is a flowchart schematically showing the method for manufacturing the silicon carbide substrate.

FIG. 3 is a schematic cross sectional view showing a structure of the silicon carbide substrate.

FIG. 4 is a schematic cross sectional view for illustrating a method for manufacturing a silicon carbide substrate.

FIG. 5 is a schematic plan view for illustrating the method for manufacturing the silicon carbide substrate.

FIG. 6 is a schematic cross sectional view for illustrating a method for manufacturing a silicon carbide substrate in a third embodiment.

FIG. 7 is a schematic cross sectional view for illustrating a method for manufacturing a silicon carbide substrate in a forth embodiment.

FIG. 8 is a schematic cross sectional view showing a structure of a vertical type MOSFET.

FIG. 9 is a flowchart schematically showing a method for manufacturing the vertical type MOSFET.

FIG. 10 is a schematic cross sectional view for illustrating the method for manufacturing the vertical type MOSFET.

FIG. 11 is a schematic cross sectional view for illustrating the method for manufacturing the vertical type MOSFET.

FIG. 12 is a schematic cross sectional view for illustrating the method for manufacturing the vertical type MOSFET.

FIG. 13 is a schematic cross sectional view for illustrating the method for manufacturing the vertical type MOSFET.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly.

### First Embodiment

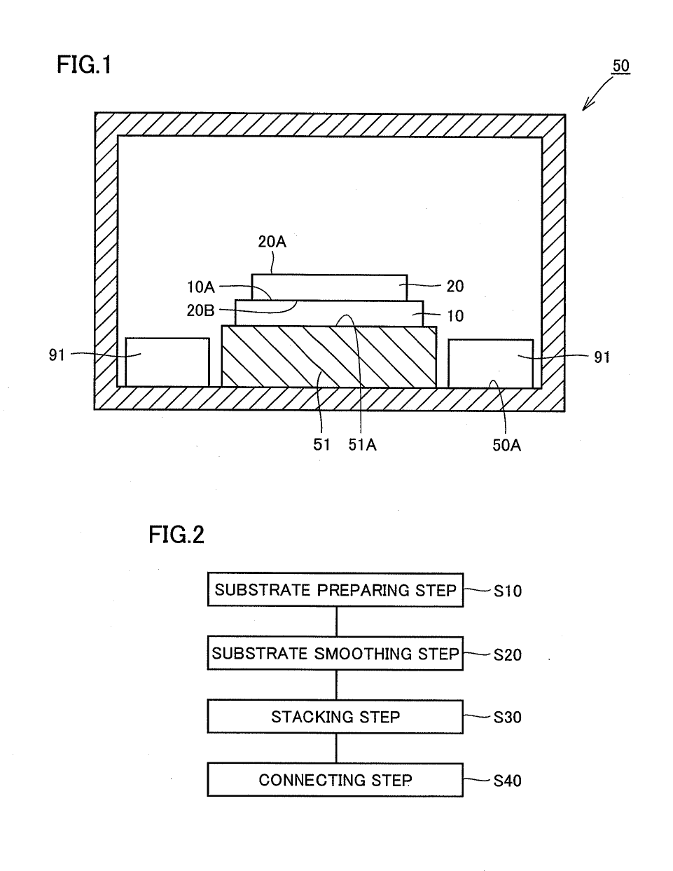

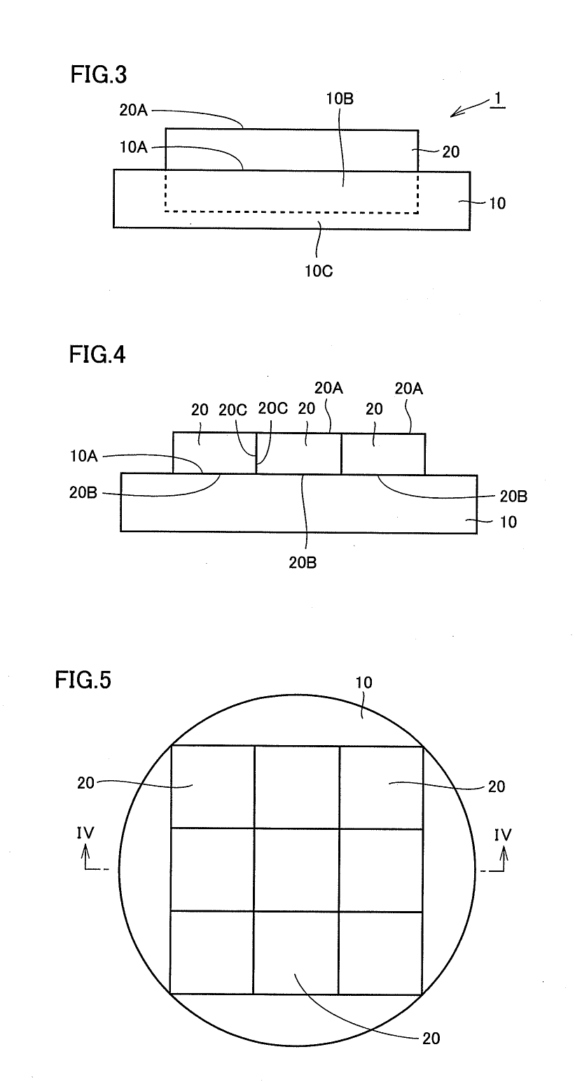

A first embodiment, which is one embodiment of the present invention, will be described first with reference to FIG. 1 and FIG. 2. Referring to FIG. 2, a substrate preparing step is first performed as a step (S10) in a method for manufacturing a silicon carbide substrate in the present embodiment. In this step (S10), referring to FIG. 1, a base substrate 10 formed of silicon carbide and a SiC substrate 20 formed of single-crystal silicon carbide are prepared. SiC substrate 20 has a main surface 20A, which will be main surface 20A of a SiC layer 20 that will be obtained by this manufacturing method (see FIG. 3 described below). Hence, on this occasion, the plane orientation of main surface 20A of SiC substrate 20 is selected in accordance with desired plane orientation of main surface 20A. Meanwhile, a substrate having an impurity concentration greater than, for example, 2×10¹⁹ cm⁻³ is adopted as base substrate 10. Further, as SiC substrate 20, there can be adopted a substrate having an impurity concentration of more than 5×10¹⁸ cm⁻³and less than 2×10¹⁹ cm⁻³. In this way, base layer 10 having a small resistivity can be formed while restraining generation of stacking fault at least in SiC layer 20 when providing heat treatment in a device process. Further, as base substrate 10, a substrate can be adopted which is formed of single-crystal silicon carbide, polycrystal silicon carbide, amorphous silicon carbide, a silicon carbide sintered compact, or the like.

Next, a substrate smoothing step is performed as a step (S20). In this step (S20), a main surface 10A of base substrate 10 and a main surface 20B of SiC substrate 20 (connection surface) are smoothed by, for example, polishing. Main surface 10A and main surface 20B are to be brought into contact with each other in a below-described step (S30). It should be noted that this step (S20) is not an essential step, but provides, if performed, a gap having a uniform size between base substrate 10 and SiC substrate 20, which are to face each other. Accordingly, in a below-described step (S40), uniformity is improved in reaction (connection) at the connection surface. This allows base substrate 10 and SiC substrate 20 to be connected to each other more securely. In order to connect base substrate 10 and the SiC substrate to each other further securely, the above-described connection surface preferably has a surface roughness Ra of less than 100 nm, more preferably, less than 50 nm. Further, by setting surface roughness Ra of the connection surface at less than 10 nm, more secure connection can be achieved.

Meanwhile, step (S20) may be omitted, i.e., step (S30) may be performed without polishing the main surfaces of base substrate 10 and SiC substrate 20, which are to be brought into contact with each other. Accordingly, manufacturing cost of silicon carbide substrate 1 can be reduced. Further, for removal of damaged layers located in surfaces formed by slicing upon fabrication of base substrate 10 and SiC substrate 20, a step of removing the damaged layers may be performed by, for example, etching instead of step (S20) or after step (S20), and then step (S30) described below may be performed.

Next, a stacking step is performed as step (S30). In this step (S30), referring to FIG. 1, SiC substrate 20 is placed on and in contact with main surface 10A of base substrate 10, thereby fabricating a stacked substrate. Here, in this step (S30), main surface 20A of SiC substrate 20 opposite to base substrate 10 may have an off angle of not less than 50° and not more than 65° relative to the {0001} plane. In this way, a silicon carbide substrate 1 can be readily manufactured in which main surface 20A of SiC layer 20 has an off angle of not less than 50° and not more than 65° relative to the {0001} plane. Further, in step (S30), the off orientation of main surface 20A forms an angle of 5° or less relative to the <1-100> direction. This facilitates formation of an epitaxial growth layer on silicon carbide substrate 1 (main surface 20A) to be fabricated. Further, in step (S30), main surface 20A may have an off angle of not less than −3° and not more than 5° relative to the {03-38} plane in the <1-100> direction. This further improves channel mobility when fabricating a MOSFET using silicon carbide substrate 1 to be manufactured.

On the other hand, in step (S30), the off orientation of main surface 20A may form an angle of 5° or smaller relative to the <11-20> direction. This facilitates formation of an epitaxial growth layer on silicon carbide substrate 1 to be fabricated.

Next, as step (S40), a connecting step is performed. In this step (S40), the stacked substrate is heated in a container to fall within a range of temperature equal to or higher than the sublimation temperature of silicon carbide constituting base substrate 10, so as to connect base substrate 10 and SiC substrate 20 to each other. Here, referring to FIG. 1, in step (S40), a crucible 50 made of graphite is used as the container for use in the heating. In crucible 50, a projecting portion 51 is provided to project from a bottom wall 50A to a central portion. The stacked substrate is placed on a top surface 51A of projecting portion 51. On portions of bottom wall 50A around projecting portion 51, silicon carbide bodies 91 made of silicon carbide are disposed distant away from projecting portion 51. By heating the stacked substrate to fall within the range of temperature equal to or greater than the sublimation temperature of silicon carbide, base substrate 10 and SiC substrate 20 are connected to each other. In other words, in step (S40), the stacked substrate is heated with silicon carbide bodies 91, made of silicon carbide and different from base substrate 10 and SiC substrate 20, being disposed in crucible 50. With the above procedure, the method for manufacturing the silicon carbide substrate in the present embodiment is completed, thereby obtaining silicon carbide substrate 1 shown in FIG. 3.

It should be noted that the above-described method for manufacturing the silicon carbide substrate may further include a step of polishing the main surface of SiC substrate 20 that corresponds to main surface 20A of SiC substrate 20 opposite to base substrate 10 in the stacked substrate. This allows a high-quality epitaxial growth layer to be formed on main surface 20A of SiC layer 20 (SiC substrate 20) opposite to base substrate 10. As a result, a semiconductor device can be manufactured which includes the high-quality epitaxial growth layer as an active layer, for example. Namely, by employing such a step, silicon carbide substrate 1 can be obtained which allows for manufacturing of a high-quality semiconductor device including the epitaxial layer formed on SiC layer 20. Here, main surface 20A of SiC substrate 20 may be polished after base substrate 10 and SiC substrate 20 are connected to each other. Alternatively, there may be polished in advance the main surface of SiC substrate 20 that is opposite to base substrate 10 and that is to be main surface 20A in the stacked substrate, thus performing the polishing before the step of fabricating the stacked substrate.

Referring to FIG. 3, silicon carbide substrate 1 obtained according to the above-described manufacturing method includes base layer 10 made of silicon carbide, and SiC layer 20 made of single-crystal silicon carbide different from that of base layer 10. Here, the expression “SiC layer 20 is made of single-crystal silicon carbide different from that of base layer 10” encompasses a case where base layer 10 is made of silicon carbide, which is not of single-crystal such as polycrystal silicon carbide or amorphous silicon carbide; and a case where base layer 10 is made of single-crystal silicon carbide different in crystal from that of SiC layer 20. The expression “base layer 10 and SiC layer 20 are made of silicon carbide different in crystal” refers to, for example, a state in which a defect density in one side relative to a boundary between base layer 10 and SiC layer 20 is different from that in the other side. In this case, the defect densities may be discontinuous at the boundary.

In the method for manufacturing silicon carbide substrate 1 in the present embodiment, silicon carbide substrate 1 is manufactured by placing SiC substrate 20 made of single-crystal silicon carbide on base substrate 10 to fabricate the stacked substrate; and heating the stacked substrate to fall within the range of temperature equal to or higher than the sublimation temperature of silicon carbide constituting base substrate 10 so as to connect base substrate 10 and SiC substrate 20 to each other. Thus, silicon carbide substrate 1 can be manufactured, for example, in the following manner. That is, base substrate 10 formed of low-quality silicon carbide crystal having a large defect density is processed to have a shape and a size suitable for manufacturing of semiconductor devices. On such a base substrate 10, a high-quality silicon carbide single-crystal not appropriately shaped is placed as SiC substrate 20. Then, they are heated. In this way, silicon carbide substrate 1 of the present invention becomes a silicon carbide substrate allowing for reduced cost of manufacturing semiconductor devices using the silicon carbide substrate.

Further, in the method for manufacturing silicon carbide substrate 1 in the present embodiment, in step (S40), silicon carbide bodies 91 made of silicon carbide and different from base substrate 10 and SiC substrate 20 are disposed in crucible 50, which is the container for attaining the connection therein. Thus, when silicon carbide constituting each of the silicon carbide bodies is sublimated, vapor pressure of the sublimation gas is increased. Accordingly, surfaces of base substrate 10 and SiC substrate 20 are restrained from being carbonized (graphitized) due to selective desorption of silicon from base substrate 10 and SiC substrate 20. Accordingly, the connection resulting from the sublimation and recrystallization of silicon carbide is developed well between base substrate 10 and SiC substrate 20.

Here, in the method for manufacturing silicon carbide substrate 1 in the present embodiment, in step (S40), silicon carbide bodies 91 may be heated to a temperature higher than that of each of base substrate 10 and SiC substrate 20. Accordingly, the vapor pressure of the sublimation gas is likely to be increased.

Further, in the method for manufacturing silicon carbide substrate 1 in the present embodiment, in step (S40), base substrate 10 may be heated to a temperature higher than that of SiC substrate 20. Accordingly, silicon carbide constituting base substrate 10 is mainly sublimated and recrystallized to achieve the connection between base substrate 10 and SiC substrate 20. As a result, silicon carbide substrate 1 can be manufactured while maintaining quality of SiC substrate 20 such as crystallinity.

Here, in the case where base substrate 10 is made of single-crystal silicon carbide, referring to FIG. 3, base layer 10 of the silicon carbide substrate to be obtained will be made of single-crystal silicon carbide. On the other hand, in the case where base substrate 10 is formed of polycrystal silicon carbide, amorphous silicon carbide, a silicon carbide sintered compact, or the like, silicon carbide constituting base substrate 10 and sublimated and recrystallized on SiC substrate 20 only forms a region which will be single-crystal layer 10B made of single-crystal silicon carbide. Namely, in such a case, referring to FIG. 3, there is obtained silicon carbide substrate 1 in which base layer 10 includes single-crystal layer 10B made of single-crystal silicon carbide so as to include main surface 10A facing SiC layer 20. With this, for example, in an early stage of a process of manufacturing a semiconductor device using silicon carbide substrate 1, silicon carbide substrate 1 is maintained to have its large thickness and is therefore readily handled, and in the middle of the process of manufacturing, a non-single-crystal region 10C, i.e., region of base layer (base substrate) 10 other than single-crystal layer 10B, is removed, whereby only single-crystal layer 10B of base layer 10 can remain within the semiconductor device. In this way, a high-quality semiconductor device can be manufactured while facilitating handling of silicon carbide substrate 1 in the process of manufacturing.

Further, in the method for manufacturing silicon carbide substrate 1 in the present embodiment, as shown in FIG. 1, each silicon carbide body 91 may be formed of bulk silicon carbide. Accordingly, by disposing silicon carbide bodies 91 distant away from the stacked substrate, silicon carbide bodies 91 and the stacked substrate are not brought into contact with each other even when gas flow is generated in crucible 50 in exhausting the gas in crucible 50, for example.

On the other hand, in the method for manufacturing silicon carbide substrate 1 in the present embodiment, instead of bulk silicon carbide bodies 91, granular silicon carbide, for example, silicon carbide powders may be employed. Accordingly, silicon carbide constituting such silicon carbide bodies 91 is effectively sublimated, thereby increasing the vapor pressure of the sublimation gas readily. In such a case, for example, it is preferable to arrange silicon carbide bodies 91 and the stacked substrate sufficiently distant away from one another so as to prevent silicon carbide bodies 91 and the stacked substrate from being brought into contact with each other even when gas flow is generated in crucible 50 in exhausting the gas in crucible 50.

Further, in the method for manufacturing silicon carbide substrate 1 in the present embodiment, in step (S40), the stacked substrate may be heated in an atmosphere obtained by reducing pressure of the atmospheric air. This reduces manufacturing cost of silicon carbide substrate 1.

Further, in the method for manufacturing silicon carbide substrate 1 in the present embodiment, in step (S40), the stacked substrate may be heated under a pressure higher than 10⁻¹ Pa and lower than 10⁴ Pa. This can accomplish the above-described connection using a simple device, and provide an atmosphere for accomplishing the connection for a relatively short time. As a result, the manufacturing cost of silicon carbide substrate 1 can be reduced.

Here, in the stacked substrate fabricated in step (S30), the gap formed between base substrate 10 and SiC substrate 20 is preferably 100 μm or smaller. Accordingly, in step (S40), uniform connection between base substrate 10 and SiC substrate 20 can be achieved.

Further, heating temperature for the stacked substrate in step (S40) is preferably not less than 1800° C. and not more than 2500° C. If the heating temperature is lower than 1800° C., it takes a long time to connect base substrate 10 and SiC substrate 20, which results in decreased efficiency in manufacturing silicon carbide substrate 1. On the other hand, if the heating temperature exceeds 2500° C., surfaces of base substrate 10 and SiC substrate 20 become rough, which may result in generation of a multiplicity of crystal defects in silicon carbide substrate 1 to be fabricated. In order to improve efficiency in manufacturing while restraining generation of defects in silicon carbide substrate 1, the heating temperature for the stacked substrate in step (S40) is set at not less than 1900° C. and not more than 2100° C.

Further, the atmosphere upon the heating in step (S40) may be inert gas atmosphere. In the case where the atmosphere is the inert gas atmosphere, the inert gas atmosphere preferably contains at least one selected from a group consisting of argon, helium, and nitrogen.

### Second Embodiment

The following describes another embodiment of the present invention, i.e., a second embodiment, with reference to FIG. 4 and FIG. 5. FIG. 4 corresponds to a cross sectional view taken along a line IV-IV in FIG. 5. A method for manufacturing a silicon carbide substrate in the second embodiment is performed in basically the same procedure as that in the method for manufacturing the silicon carbide substrate in the first embodiment, and provides effects similar to those in the first embodiment. However, the method for manufacturing the silicon carbide substrate in the second embodiment is different from the method of the first embodiment in that in step (S30), a plurality of SiC substrates 20 are placed and arranged side by side when viewed in a planar view.

In other words, in the method for manufacturing the silicon carbide substrate in the present embodiment, in step (S10), base substrate 10 is first prepared as with the first embodiment and the plurality of SiC substrates 20 are prepared. Next, step (S20) is performed in the same way as in the first embodiment, as required. Thereafter, referring to FIG. 4 and FIG. 5, in step (S30), the plurality of SiC substrates 20 are placed and arranged side by side on main surface 10A of base substrate 10 when viewed in a planar view, so as to fabricate a stacked substrate. In other words, the plurality of SiC substrates 20 are disposed on and along main surface 10A of base substrate 10.

More specifically, nine SiC substrates 20 are arranged on main surface 10A of base substrate 10 in the form of a matrix such that adjacent SiC substrates 20 are in contact with each other. Thereafter, step (S40) is performed in the same way as in the first embodiment to obtain silicon carbide substrate 1. In the present embodiment, in step (S30), the plurality of SiC substrates 20 are placed on base substrate 10, and the plurality of SiC substrates 20 and base substrate 10 are connected to one another in step (S40). Thus, the method for manufacturing the silicon carbide substrate in the present embodiment allows for manufacturing of silicon carbide substrate 1 that can be handled as a substrate having a high-quality SiC layer 20 and a large bore diameter. Utilization of such a silicon carbide substrate 1 allows for efficient manufacturing process of semiconductor devices.

Further, referring to FIG. 4, each of SiC substrates 20 preferably has an end surface 20C substantially perpendicular to main surface 20A of SiC substrate 20. In this way, silicon carbide substrate 1 can be readily formed. Here, for example, when end surface 20C and main surface 20A form an angle of not less than 85° and not more than 95°, it can be determined that end surface 20C and main surface 20A are substantially perpendicular to each other.

### Third Embodiment

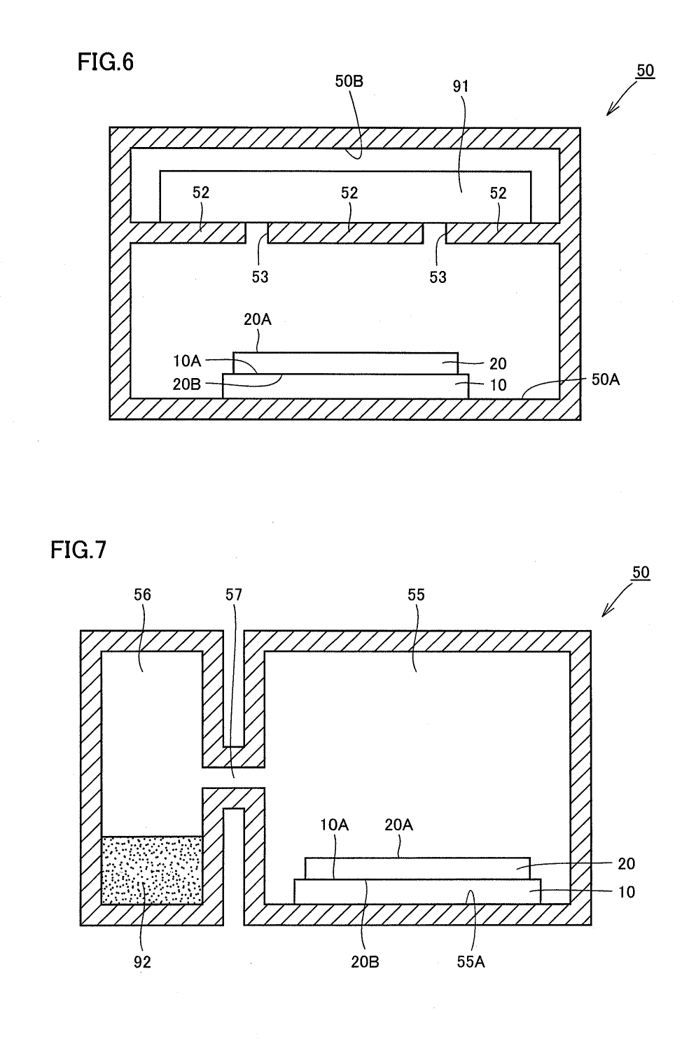

The following describes still another embodiment of the present invention, i.e., a third embodiment. A method for manufacturing a silicon carbide substrate in the third embodiment is performed in basically the same manner as that in the method for manufacturing the silicon carbide substrate in the first embodiment, and provides effects similar to those in the first embodiment. However, in the method for manufacturing the silicon carbide substrate in the third embodiment, referring to FIG. 6 and FIG. 1, a crucible 50 different from that in the first embodiment is employed.

Specifically, referring to FIG. 6, crucible 50 in the third embodiment has a bottom wall 50A and a top wall 50B, between which a separating wall 52 is formed. Separating wall 52 is provided with communication holes 53 each communicating a region of the bottom wall 50A side with a region of the top wall 50B side. Using such a crucible 50, the method for manufacturing the silicon carbide substrate is performed as follows.

First, step (S10) is performed in the same way as in the first embodiment. Next, step (S20) is performed in the same way as in the first embodiment, as required. Further, step (S30) is also performed in the same way as in the first embodiment so as to fabricate a stacked substrate. Thereafter, in step (S40), the stacked substrate is placed on bottom wall 50A of crucible 50. Meanwhile, a bulk silicon carbide body 91 is placed at the top wall SOB side relative to separating wall 52. Then, the stacked substrate is heated in the same manner as in the first embodiment, thereby connecting base substrate 10 and SiC substrate 20 to each other. In this way, silicon carbide substrate 1 is manufactured. According to the method for manufacturing the silicon carbide substrate in the present embodiment, crucible 50 including separating wall 52 as described above is employed. Hence, even though the stacked substrate is directly placed on bottom wall 50A, silicon carbide body 91 and the stacked substrate are not brought into contact with each other without paying any particular attention to a positional relation between silicon carbide body 91 and the stacked substrate.

### Fourth Embodiment

The following describes yet another embodiment of the present invention, i.e., a fourth embodiment. A method for manufacturing a silicon carbide substrate in the fourth embodiment is performed in basically the same manner as that in the method for manufacturing the silicon carbide substrate in the first embodiment, and provides effects similar to those in the first embodiment. However, in the method for manufacturing the silicon carbide substrate in the fourth embodiment, referring to FIG. 7 and FIG. 1, a crucible 50 different from that in the first embodiment is employed.

Specifically, crucible 50 in the fourth embodiment includes a main chamber 55 in which the stacked substrate is to be disposed, an auxiliary chamber 56 in which a silicon carbide body 92 is to be disposed, and a communication path 57 communicating main chamber 55 with auxiliary chamber 56. Using such a crucible 50, the method for manufacturing the silicon carbide substrate is performed as follows.

First, step (S10) is performed in the same way as in the first embodiment. Next, step (S20) is performed in the same way as in the first embodiment, as required. Further, step (S30) is also performed in the same way as in the first embodiment, thereby fabricating the stacked substrate. Thereafter, in step (S40), the stacked substrate is placed on bottom wall 55A of main chamber 55. Meanwhile, granular (powdery) silicon carbide body 92 is disposed in auxiliary chamber 56. Then, the stacked substrate is heated in the same manner as in the first embodiment, thereby connecting base substrate 10 and SiC substrate 20 to each other. In this way, silicon carbide substrate 1 is manufactured. According to the method for manufacturing the silicon carbide substrate in the present embodiment, crucible 50 having the above-described structure is employed. Hence, although powdery silicon carbide body 92 is used, silicon carbide body 92 is not in direct contact with the stacked substrate. Thus, silicon carbide constituting silicon carbide body 92 is efficiently sublimated, thereby readily increasing vapor pressure of the sublimation gas in main chamber 55.

### Fifth Embodiment

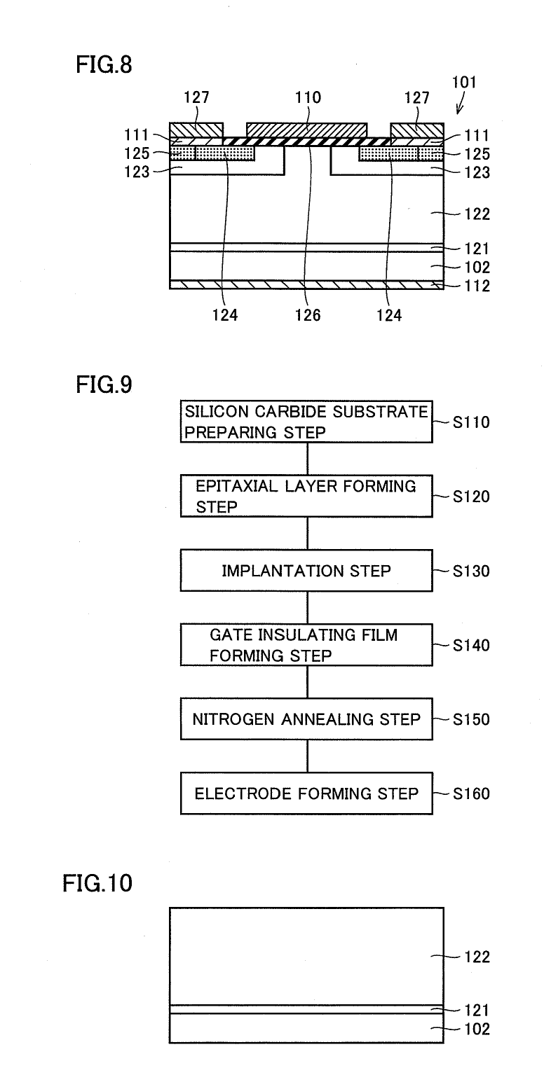

As a fifth embodiment, the following describes one exemplary semiconductor device fabricated using the above-described silicon carbide substrate of the present invention. Referring to FIG. 8, a semiconductor device 101 according to the present invention is a DiMOSFET (Double Implanted MOSFET) of vertical type, and has a substrate 102, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112 formed on the backside surface of substrate 102. Specifically, buffer layer 121 made of silicon carbide is formed on the front-side surface of substrate 102 made of silicon carbide of n type conductivity. Employed as substrate 102 is the silicon carbide substrate manufactured in accordance with a method for manufacturing a silicon carbide substrate in the present invention, i.e., method inclusive of those described in the first to fourth embodiments. In the case where silicon carbide substrate 1 in each of the first to fourth embodiments is employed, buffer layer 121 is formed on SiC layer 20 of silicon carbide substrate 1. Buffer layer 121 has n type conductivity, and has a thickness of, for example, 0.5 μm. Further, impurity with n type conductivity in buffer layer 121 has a concentration of, for example, 5×10¹⁷ cm⁻³. Formed on buffer layer 121 is reverse breakdown voltage holding layer 122. Reverse breakdown voltage holding layer 122 is made of silicon carbide of n type conductivity, and has a thickness of 10 μm, for example. Further, reverse breakdown voltage holding layer 122 includes an impurity of n type conductivity at a concentration of, for example, 5×10¹⁵ cm⁻³.

Reverse breakdown voltage holding layer 122 has a surface in which p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. Oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed. Moreover, drain electrode 112 is formed on the backside surface of substrate 102, i.e., the surface opposite to its front-side surface on which buffer layer 121 is formed.

Semiconductor device 101 in the present embodiment employs, as substrate 102, the silicon carbide substrate manufactured in accordance with the method for manufacturing the silicon carbide substrate in the present invention, i.e., method inclusive of those described in the first to fourth embodiments. Namely, semiconductor device 101 includes: substrate 102 serving as the silicon carbide substrate; buffer layer 121 and reverse breakdown voltage holding layer 122 both serving as epitaxial growth layers formed on and above substrate 102; and source electrodes 111 formed on reverse breakdown voltage holding layer 122. Further, substrate 102 is manufactured in accordance with the method for manufacturing the silicon carbide substrate in the present invention. Here, as described above, the substrate manufactured in accordance with the method for manufacturing the silicon carbide substrate in the present invention allows for reduced manufacturing cost of semiconductor devices. Hence, semiconductor device 101 is manufactured with the reduced manufacturing cost.

The following describes a method for manufacturing semiconductor device 101 shown in FIG. 8, with reference to FIG. 9-FIG. 13. Referring to FIG. 9, first, a silicon carbide substrate preparing step (S110) is performed. Prepared here is, for example, substrate 102, which has its main surface corresponding to the (03-38) plane and made of silicon carbide (see FIG. 9). As substrate 102, there is prepared a silicon carbide substrate of the present invention, inclusive of silicon carbide substrate 1 manufactured in accordance with each of the manufacturing methods described in the first to fourth embodiments.

As substrate 102 (see FIG. 10), a substrate may be employed which has n type conductivity and has a substrate resistance of 0.02 Ωcm.

Next, as shown in FIG. 9, an epitaxial layer forming step (S120) is performed. Specifically, buffer layer 121 is formed on the front-side surface of substrate 102. Buffer layer 121 is formed on main surface 20A (see FIG. 3) of SiC layer 20 of silicon carbide substrate 1 employed as substrate 102. As buffer layer 121, an epitaxial layer is formed which is made of silicon carbide of n type conductivity and has a thickness of 0.5 μm, for example. Buffer layer 121 has a conductive impurity at a density of, for example, 5×10¹⁷ cm⁻³. Then, on buffer layer 121, reverse breakdown voltage holding layer 122 is formed as shown in FIG. 10. As reverse breakdown voltage holding layer 122, a layer made of silicon carbide of n type conductivity is formed using an epitaxial growth method. Reverse breakdown voltage holding layer 122 can have a thickness of, for example, 10 μm. Further, reverse breakdown voltage holding layer 122 includes an impurity of n type conductivity at a density of for example, 5×10¹⁵ cm⁻³.

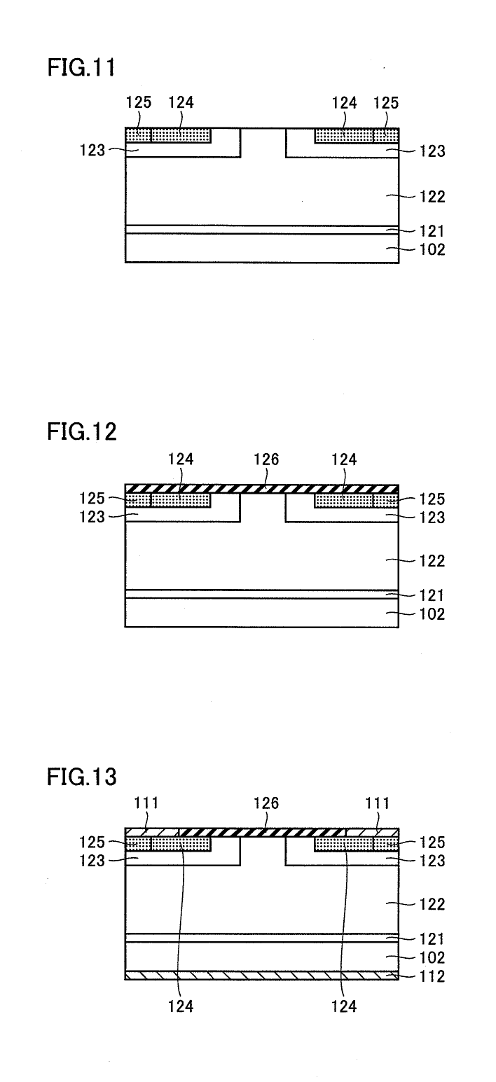

Next, as shown in FIG. 9, an implantation step (S130) is performed. Specifically, an impurity of p type conductivity is implanted into reverse breakdown voltage holding layer 122 using, as a mask, an oxide film formed through photolithography and etching, thereby forming p regions 123 as shown in FIG. 11. Further, after removing the oxide film thus used, an oxide film having a new pattern is formed through photolithography and etching. Using this oxide film as a mask, a conductive impurity of n type conductivity is implanted into predetermined regions to form n⁺ regions 124. In a similar way, a conductive impurity of p type conductivity is implanted to form p⁺ regions 125. As a result, the structure shown in FIG. 11 is obtained.

After such an implantation step, an activation annealing process is performed. This activation annealing process can be performed under conditions that, for example, argon gas is employed as atmospheric gas, heating temperature is set at 1700° C., and heating time is set at 30 minutes.

Next, a gate insulating film forming step (S140) is performed as shown in FIG. 9. Specifically, as shown in FIG. 12, oxide film 126 is formed to cover reverse breakdown voltage holding layer 122, p regions 123, n⁺ regions 124, and p⁺ regions 125. As a condition for forming oxide film 126, for example, dry oxidation (thermal oxidation) may be performed. The dry oxidation can be performed under conditions that the heating temperature is set at 1200° C. and the heating time is set at 30 minutes.

Thereafter, a nitrogen annealing step (S150) is performed as shown in FIG. 9. Specifically, an annealing process is performed in atmospheric gas of nitrogen monoxide (NO). Temperature conditions for this annealing process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125, which are disposed below oxide film 126. Further, after the annealing step using the atmospheric gas of nitrogen monoxide, additional annealing may be performed using argon (Ar) gas, which is an inert gas. Specifically, using the atmospheric gas of argon gas, the additional annealing may be performed under conditions that the heating temperature is set at 1100° C. and the heating time is set at 60 minutes.

Next, as shown in FIG. 9, an electrode forming step (S160) is performed. Specifically, a resist film having a pattern is formed on oxide film 126 by means of the photolithography method. Using the resist film as a mask, portions of the oxide film above n⁺ regions 124 and p⁺ regions 125 are removed by etching. Thereafter, a conductive film such as a metal is formed on the resist film and formed in openings of oxide film 126 in contact with n⁺ regions 124 and p⁺ regions 125. Thereafter, the resist film is removed, thus removing the conductive film's portions located on the resist film (lift-off). Here, as the conductor, nickel (Ni) can be used, for example. As a result, as shown in FIG. 13, source electrodes 111 can be obtained. It should be noted that on this occasion, heat treatment for alloying is preferably performed. Specifically, using atmospheric gas of argon (Ar) gas, which is an inert gas, the heat treatment (alloying treatment) is performed with the heating temperature being set at 950° C. and the heating time being set at 2 minutes.

Thereafter, on source electrodes 111, upper source electrodes 127 (see FIG. 8) are formed. Further, gate electrode 110 (see FIG. 8) is formed on oxide film 126. Furthermore, drain electrode 112 is formed (see FIG. 8). In this way, semiconductor device 101 shown in FIG. 8 can be obtained.

It should be noted that in the fifth embodiment, the vertical type MOSFET has been illustrated as one exemplary semiconductor device that can be fabricated using the silicon carbide substrate of the present invention, but the semiconductor device that can be fabricated is not limited to this. For example, various types of semiconductor devices can be fabricated using the silicon carbide substrate of the present invention, such as a JFET (Junction Field Effect Transistor), an IGBT (Insulated Gate Bipolar Transistor), and a Schottky barrier diode.

Further, the fifth embodiment has illustrated a case where the semiconductor device is fabricated by forming the epitaxial layer, which serves as an active layer, on the silicon carbide substrate having its main surface corresponding to the (03-38) plane. However, the crystal plane that can be adopted for the main surface is not limited to this and any crystal plane suitable for the purpose of use and including the (0001) plane can be adopted for the main surface.

Further, as the main surface (main surface 20A of SiC substrate (SiC layer) 20 of silicon carbide substrate 1), there can be adopted a main surface having an off angle of not less than −3° and not more than +5° relative to the (0-33-8) plane in the <01-10> direction, so as to further improve channel mobility in the case where a MOSFET or the like is fabricated using the silicon carbide substrate. Here, the (0001) plane of single-crystal silicon carbide of hexagonal crystal is defined as the silicon plane whereas the (000-1) plane is defined as the carbon plane. Meanwhile, the “off angle relative to the (0-33-8) plane in the <01-10> direction” refers to an angle formed by the orthogonal projection of a normal line of the main surface to a flat plane defined by the <000-1> direction and the <01-10> direction serving as a reference for the off orientation, and a normal line of the (0-33-8) plane. The sign of a positive value corresponds to a case where the orthogonal projection approaches in parallel with the <01-10> direction, whereas the sign of a negative value corresponds to a case where the orthogonal projection approaches in parallel with the <000-1> direction. Further, the expression “the main surface having an off angle of not less than −3° and not more than +5° relative to the (0-33-8) plane in the <01-10> direction” indicates that the main surface corresponds to a plane, at the carbon plane side, which satisfies the above-described conditions in the silicon carbide crystal. It should be noted that in the present application, the (0-33-8) plane includes an equivalent plane, at the carbon plane side, which is expressed in a different manner due to determination of an axis for defining a crystal plane, and does not include a plane at the silicon plane side.

### EXAMPLE

In order to confirm the effects provided by the method for manufacturing the silicon carbide substrate in the present invention, an experiment was conducted to manufacture a silicon carbide substrate, in accordance with the same procedure as that in each of the above-described embodiments. The experiment was conducted in the following manner.

First, as the base substrate, a substrate was prepared which was made of single-crystal silicon carbide, had a diameter φ of 2 inches, had a thickness of 300 μm, had a polytype of 4H, had a main surface corresponding to the (03-38) plane, had an n type impurity concentration of 2×10¹⁹ cm⁻³, had a micro pipe density of 1×10⁴ cm⁻², and had a stacking fault density of 1×10⁵ cm⁻¹. Meanwhile, as the SiC substrate, a substrate was prepared which was made of single-crystal silicon carbide, had a planar shape of square having each side of 20 mm, had a thickness of 300 μm, had a polytype of 4H, had a main surface corresponding to the (03-38) plane, had an n type impurity concentration of 1×10¹⁹ cm³, had a micro pipe density of 0.2 cm⁻², and had a stacking fault density of less than 1 cm⁻¹.

Next, a plurality of the SiC substrates were placed and arranged side by side on the base substrate so as not to overlap with one another, thereby obtaining a stacked substrate. The stacked substrate thus obtained was then placed in a container (crucible) made of graphite. Further, as the silicon carbide body, silicon carbide powders each having a grain size of 200 μm or smaller were disposed in the crucible so as not to be in contact with the stacked substrate. Then, the stacked substrate was heated to reach or exceed 2000° C. while heating the silicon carbide powders for sublimation to connect the base substrate and the SiC substrates to one another.

As a result, as compared with a case where no silicon carbide powders are disposed, graphitization was restrained in the vicinity of surfaces of the base substrate and the SiC substrates, thereby achieving good connection between the base substrate and each of the SiC substrates. It is considered that this is due to the following reason. That is, sublimation gas from the silicon carbide powders caused increase of vapor pressure of the sublimation gas in the crucible, thereby restraining selective (preferential) desorption of silicon.

It should be noted that the base substrate (base layer) preferably has a diameter of 2 inches or greater, more preferably, 6 inches or greater in the method for manufacturing the silicon carbide substrate, the method for manufacturing the semiconductor device, the silicon carbide substrate, and the semiconductor device in the present invention. Further, in consideration of application thereof to a power device, silicon carbide constituting the SiC layer (SiC substrate) preferably has a polytype of 4H. In addition, each of the base substrate and the SiC substrate preferably has the same crystal structure. Moreover, a difference in thermal expansion coefficient between the base layer and the SiC layer is preferably small enough to generate no cracks in the process of manufacturing the semiconductor device using the silicon carbide substrate. Further, in each of the base substrate and the SiC substrate, variation in the thickness thereof is small, specifically, the variation of the thickness thereof is preferably 10 μm or smaller. Meanwhile, in consideration of application thereof to a vertical type device in which electric current flows in the direction of thickness of the silicon carbide substrate, the base layer preferably has an electrical resistivity of less than 50 mΩcm, more preferably, less than 10 mΩcm. Meanwhile, in order to facilitate handling thereof, the silicon carbide substrate preferably has a thickness of 300 μm or greater. Further, the heating of the stacked substrate in the step of connecting the base substrate and the SiC substrate can be performed using, for example, a resistive heating method, a high-frequency induction heating method, a lamp annealing method, or the like.

The method for manufacturing the silicon carbide substrate, the method for manufacturing the semiconductor device, the silicon carbide substrate, and the semiconductor device in the present invention are particularly advantageously applicable to a method for manufacturing a silicon carbide substrate, a method for manufacturing a semiconductor device, a silicon carbide substrate, and a semiconductor device, each of which is required to achieve reduced manufacturing cost of a semiconductor device that employs a silicon carbide substrate.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a base substrate made of silicon carbide and a SiC substrate made of single-crystal silicon carbide;
fabricating a stacked substrate by placing said SiC substrate on and in contact with a main surface of said base substrate; and
connecting said base substrate and said SiC substrate to each other by heating said stacked substrate in a container to fall within a range of temperature equal to or greater than a sublimation temperature of silicon carbide constituting said base substrate,
in the step of connecting said base substrate and said SiC substrate, a silicon carbide body made of silicon carbide and different from said base substrate and said SiC substrate being disposed in said container.

2. The method for manufacturing the silicon carbide substrate according to claim 1, wherein in the step of connecting said base substrate and said SiC substrate, said base substrate is heated to a temperature higher than that of said SiC substrate.

3. The method for manufacturing the silicon carbide substrate according to claim 1, wherein said silicon carbide body is formed of bulk silicon carbide.

4. The method for manufacturing the silicon carbide substrate according to claim 1, wherein said silicon carbide body is formed of granular silicon carbide.

5. The method for manufacturing the silicon carbide substrate according to claim 1, wherein graphite is employed as a material to form said container.

6. The method for manufacturing the silicon carbide substrate according to claim 1, further comprising the step of smoothing main surfaces of said base substrate and said SiC substrate before the step of fabricating said stacked substrate, said main surfaces of said base substrate and said SiC substrate being to be brought into contact with each other in the step of fabricating said stacked substrate.

7. The method for manufacturing the silicon carbide substrate according to claim 1, wherein the step of fabricating said stacked substrate is performed without polishing main surfaces of said base substrate and said SiC substrate before the step of fabricating said stacked substrate, said main surfaces of said base substrate and said SiC substrate being to be brought into contact with each other in the step of fabricating said stacked substrate.

8. The method for manufacturing the silicon carbide substrate according to claim 1, wherein in the step of fabricating said stacked substrate, a plurality of said SiC substrates are placed and arranged side by side when viewed in a planar view.

9. The method for manufacturing the silicon carbide substrate according to claim 1, wherein in the step of fabricating said stacked substrate, said SiC substrate has a main surface opposite to said base substrate and having an off angle of not less than 50° and not more than 65° relative to a {0001} plane.

10. The method for manufacturing the silicon carbide substrate according to claim 9, wherein in the step of fabricating said stacked substrate, said main surface of said SiC substrate opposite to said base substrate has an off orientation which forms an angle of 5° or smaller relative to a <1-100> direction.

11. The method for manufacturing the silicon carbide substrate according to claim 10, wherein in the step of fabricating said stacked substrate, said main surface of said SiC substrate opposite to said base substrate has an off angle of not less than −3° and not more than 5° relative to a {03-38} plane in the <1-100> direction.

12. The method for manufacturing the silicon carbide substrate according to claim 9, wherein in the step of fabricating said stacked substrate, said main surface of said SiC substrate opposite to said base substrate has an off orientation which forms an angle of 5° or smaller relative to a <11-20> direction.

13. The method for manufacturing the silicon carbide substrate according to claim 1, wherein in the step of connecting said base substrate and said SiC substrate, said stacked substrate is heated in an atmosphere obtained by reducing pressure of atmospheric air.

14. The method for manufacturing the silicon carbide substrate according to claim 1, wherein in the step of connecting said base substrate and said SiC substrate, said stacked substrate is heated under a pressure higher than 10⁻¹ Pa and lower than 10⁴ Pa.

15. A method for manufacturing a semiconductor device, comprising the steps of:
preparing a silicon carbide substrate;
forming an epitaxial growth layer on said silicon carbide substrate; and
forming an electrode on said epitaxial growth layer,
in the step of preparing said silicon carbide substrate, said silicon carbide substrate being manufactured using the method for manufacturing the silicon carbide substrate as recited in claim 1.

16. A silicon carbide substrate manufactured using the method for manufacturing the silicon carbide substrate as recited in claim 1.

17. A semiconductor device manufactured using the method for manufacturing the semiconductor device as recited in claim 15.
